(19) United States
(12) Patent Application Publication
(10) Pub. No.: US 2008/0242036 A1
(43) Pub. Date: Oct. 2, 2008

(54) SEMICONDUCTOR DEVICE AND MANUFACTURING METHOD THEREOF

(75) Inventor: Hirokazu Hisamatsu, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 12/053,689

(22) Filed: Mar. 24, 2008

(30) Foreign Application Priority Data
Mar. 28, 2007 (JP) 2007-084027

(51) Int. Cl. H01L 21/76; H01L 21/336

(52) U.S. Cl. 438/297; 438/443; 257/E21.409; 257/E21.09

(57) ABSTRACT

A method for manufacturing a semiconductor device, includes: a) forming a first semiconductor layer on a semiconductor substrate; b) forming a second semiconductor layer on the first semiconductor layer; c) sequentially etching a part of the second semiconductor layer and a part of the first semiconductor layer so as to form a first groove exposing the first semiconductor layer; d) forming a cavity between the semiconductor substrate and the second semiconductor layer by etching the first semiconductor layer through the first groove under an etching condition in which the first semiconductor layer is more easily etched than the second semiconductor layer; e) forming an embedded oxide film in the cavity; f) etching the embedded oxide film from a lateral surface side thereof so as to form a gap between a peripheral part of the second semiconductor layer and the semiconductor substrate; and g) forming an insulating etching stopper layer in the gap.

The entire disclosure of Japanese Patent Application No. 2007-084027, filed Mar. 28, 2007 is expressly incorporated by reference herein.

### BACKGROUND

1. Technical Field

The present invention relates to a method for manufacturing a semiconductor device, and a semiconductor device. More particularly, the present invention relates to a technique for forming a silicon-on-insulator (SOI) structure on a semiconductor substrate.

2. Related Art

For high performance of a semiconductor device, such effort has been made that a transistor is formed on a thin film silicon layer (hereinafter, also referred to as an “SOI (silicon on insulator) layer”) which is formed on an insulating film so as to manufacture a semiconductor integrated circuit that isolates a circuit element thereof by a dielectric and has small stray capacitance. As a technique for forming an SOI structure on a required position of a bulk-Si substrate, a method is disclosed for example in JP-A-2005-354024 and T. Sakai et al., Separation by Bonding Si islands (SBSI) for LSI Application., Second International SiGe Technology and Device Meeting, Meeting Abstract, pp. 230-231, May (2004). Other examples of related art are disclosed in J. Widiez et al., IEEE International SOI Conference, p. 185, 2004; Int. Tech. Roadmap for Semicond., ED. 2003; and D. J. Frank et al., IEDM, p 553, 1992.

The method disclosed in these examples is also called Separation by Bonding Si Islands (SBSI) method in which an SOI structure is formed on a part of a bulk partially. In the SBSI method, a Si layer and a SiGe layer are formed on a Si substrate, and only the SiGe layer is selectively removed by using difference of an etching rate between Si and SiGe so as to form a cavity between the Si substrate and the Si layer. An upper surface of the Si substrate and a lower surface of the Si layer facing the cavity are thermally oxidized so as to form a SiO₂ film (hereinafter, also referred to as a BOX layer) between the Si substrate and the Si layer. Then a SiO₂ film and the like are formed on the Si substrate by CVD, and they are planarized and etched by a diluted hydrofluoric acid (HF) solution and the like so as to expose a surface of the Si layer (hereinafter, also called as an SOI layer) formed on the BOX layer.

In such method, a manufacturing cost that is a major issue for an SOI device can be reduced and an SOI transistor and a Bulk transistor can be mounted together. Accordingly, a chip area can be reduced while maintaining advantages of the SOI transistor and the Bulk transistor.

Here, since an SOI device is formed on a thin film SOI layer, a manufacturing process thereof is harder than that of a bulk-Si device that is formed on a common bulk-Si substrate. Especially, forming a contact hole on the thin film SOI layer is one of the major issues in the process.

That is, in order to ensure a communication with the SOI layer, an interlayer insulating film covering the SOI layer has to be over-etched in dry-etching for forming the contact hole. However, if time for over-etching with respect to the interlayer insulating film is too long, not only the SOI layer but also the BOX layer are etched. At worst, a contact hole is formed such that the hole penetrates through both of the SOI layer and the BOX layer. If the contact hole reaches a surface of the Si substrate, a source and a drain formed on the SOI layer are short-circuited, for example, incorrectly operating the SOI device disadvantageously.

### SUMMARY

An advantage of the present invention is to provide a method for manufacturing a semiconductor device. The method can prevent a contact hole from reaching a surface of the semiconductor substrate. Another advantage of the invention is to provide a semiconductor device having high reliability.

A method for manufacturing a semiconductor device according to a first aspect of the invention, includes: a) forming a first semiconductor layer on a semiconductor substrate; b) forming a second semiconductor layer on the first semiconductor layer; c) sequentially etching a part of the second semiconductor layer and a part of the first semiconductor layer so as to form a first groove exposing the first semiconductor layer; d) forming a cavity between the semiconductor substrate and the second semiconductor layer by etching the first semiconductor layer through the first groove under an etching condition in which the first semiconductor layer is more easily etched than the second semiconductor layer; e) forming an embedded oxide film in the cavity; f) etching the embedded oxide film from a lateral surface side thereof so as to form a gap between a peripheral part of the second semiconductor layer and the semiconductor substrate; and g) forming an insulating etching stopper layer in the gap.

Here, the “etching stopper layer” has a lower etching speed than the “oxide film”, namely, is hard to be etched and has a function to prevent the progress of the etching. In a case where the oxide film is a silicon oxide (SiO₂) film, a silicon nitride (Si₃N₄) film can be used, for example, as the etching stopper layer.

The method according to the first aspect of the invention further includes:, between the step b) and the step d), h) etching a part of the second semiconductor layer and a part of the first semiconductor layer so as to form a second groove penetrating the second semiconductor layer and the first semiconductor layer; and i) forming a support to support the second semiconductor layer at least in the second groove.

The method of the first aspect, further includes: j) forming a transistor on the second semiconductor layer; k) forming an interlayer insulation film over the semiconductor substrate in a manner covering the transistor; and l) partially etching the interlayer insulation film so as to form a contact hole on one of a source and a drain of the transistor. In the step j), one of the source and the drain is formed at the peripheral part that positions directly above the etching stopper layer.

According to the method of the first aspect, for example, even if partial etching of the interlayer insulation film for forming a contact hole that exposes the second semiconductor layer as its lower surface progresses excessively such that the contact hole penetrates through the second semiconductor layer, the progress of the etching can be stopped at the etching stopper layer. Therefore, the contact hole can be prevented from reaching the surface of the semiconductor substrate, being able to prevent such defect that the source and the drain of the transistor formed on the second semiconductor layer are short circuited through the semiconductor substrate.

A method for manufacturing a semiconductor device according to a second aspect of the invention, includes: a) forming a first semiconductor layer on a semiconductor substrate; b) forming a second semiconductor layer on the first semiconductor layer; c) forming a third semiconductor layer made of a same material as that of the first semiconductor layer on the second semiconductor layer; d) forming a fourth semiconductor layer made of a same material as that of the second semiconductor layer on the third semiconductor layer; e) partially etching the fourth semiconductor layer, the third semiconductor layer, the second semiconductor layer, and the first semiconductor layer in sequence so as to form a groove exposing the third semiconductor layer and the first semiconductor layer; f) forming a first cavity between the semiconductor substrate and the second semiconductor layer; and a second cavity between the second semiconductor layer and the fourth semiconductor layer by etching the first semiconductor layer and the third semiconductor layer through the groove under a condition in which the first semiconductor layer is more easily etched than the second semiconductor layer; g) forming a first embedded oxide film in the first cavity; h) forming a second embedded oxide film in the second cavity; i) partially etching the second embedded oxide film from a lateral surface side thereof so as to form a gap between a peripheral part of the fourth semiconductor layer and the second semiconductor layer; and j) forming an insulating etching stopper layer in the gap.

Here, a transistor is formed on the fourth semiconductor layer, for example, and the second semiconductor layer is used as a back gate electrode (for adjusting a threshold value of the transistor), for example.

According to the method of the second aspect, for example, even if partial etching of the interlayer insulation layer for forming a contact hole that exposes the second semiconductor layer as its lower surface progresses excessively such that the contact hole penetrates through the second semiconductor layer, the progress of the etching can be stopped at the etching stopper layer. Therefore, the contact hole of which a lower surface should be the fourth semiconductor layer can be prevented from penetrating through the fourth semiconductor layer to reach a surface of the second semiconductor layer. Thus such defect that a source or a drain of the transistor formed on the fourth semiconductor layer is short circuited can be prevented.

The method of the second aspect, further includes: if the gap is defined as a first gap, k) partially etching the first embedded oxide film from a lateral surface side thereof so as to form a second gap between a peripheral part of the second semiconductor layer and the semiconductor substrate; and l) forming an etching stopper layer in the second gap as well.

According to the method of the second aspect, for example, even if etching for forming the contact hole that exposes the second semiconductor layer as its lower surface progresses excessively such that a contact hole penetrates through the second semiconductor layer, the progress of the etching can be stopped at the etching stopper layer. Thus the contact hole is prevented from reaching the surface of the semiconductor substrate. Therefore, in a case where the second semiconductor layer is used as a back gate electrode, for example, such defect that a back gate bias is applied involuntarily to the semiconductor substrate can be prevented.

A semiconductor device according to a third aspect of the invention, includes: an insulating layer formed on a part of a semiconductor substrate; a semiconductor layer formed on the insulating layer; and an etching stopper layer that is formed between a peripheral part of the semiconductor layer and the semiconductor substrate without being formed between a center part of the semiconductor layer and the semiconductor substrate. In the device, one of a source and a drain of a transistor and a contact hole communicating with the one of the source and the drain are formed directly above the etching stopper layer.

In such structure, when a contact hole is formed on a source or a drain of the transistor, the contact hole can be prevented from reaching a surface of the semiconductor substrate. Thus such defect that the source and the drain are short circuited through the semiconductor substrate can be prevented.

Consequently, a semiconductor device having high reliability can be provided.

### BRIEF DESCRIPTION OF THE DRAWINGS

The invention will be described with reference to the accompanying drawings, wherein like numbers reference like elements.

FIGS. 1A and 1B are diagrams showing a method for manufacturing a semiconductor device according to a first embodiment (first step).

FIGS. 2A and 2B are diagrams showing the method for manufacturing a semiconductor device according to the first embodiment (second step).

FIGS. 3A and 3B are diagrams showing the method for manufacturing a semiconductor device according to the first embodiment (third step).

FIGS. 4A to 4C are diagrams showing the method for manufacturing a semiconductor device according to the first embodiment (fourth step).

FIGS. 5A and 5B are diagrams showing the method for manufacturing a semiconductor device according to the first embodiment (fifth step).

FIGS. 6A and 6B are diagrams showing the method for manufacturing a semiconductor device according to the first embodiment (sixth step).

FIGS. 7A to 7C are diagrams showing the method for manufacturing a semiconductor device according to the first embodiment (seventh step).

FIGS. 8A to 8C are diagrams showing the method for manufacturing a semiconductor device according to the first embodiment (eighth step).

FIGS. 9A and 9B are diagrams showing the method for manufacturing a semiconductor device according to the first embodiment (ninth step).

FIGS. 10A to 10D are diagrams showing a method for manufacturing a semiconductor device according to a second embodiment (first step).

FIGS. 11A and 11B are diagrams showing the method for manufacturing a semiconductor device according to the second embodiment (second step).

FIGS. 12A to 12D are diagrams showing a method for manufacturing a semiconductor device according to a third embodiment (first step).

FIGS. 13A to 13C are diagrams showing the method for manufacturing a semiconductor device according to the third embodiment (second step).

### DESCRIPTION OF THE PREFERRED EMBODIMENTS

Hereinafter, embodiments of the present invention will be described with reference to the accompanying drawings.

### First Embodiment

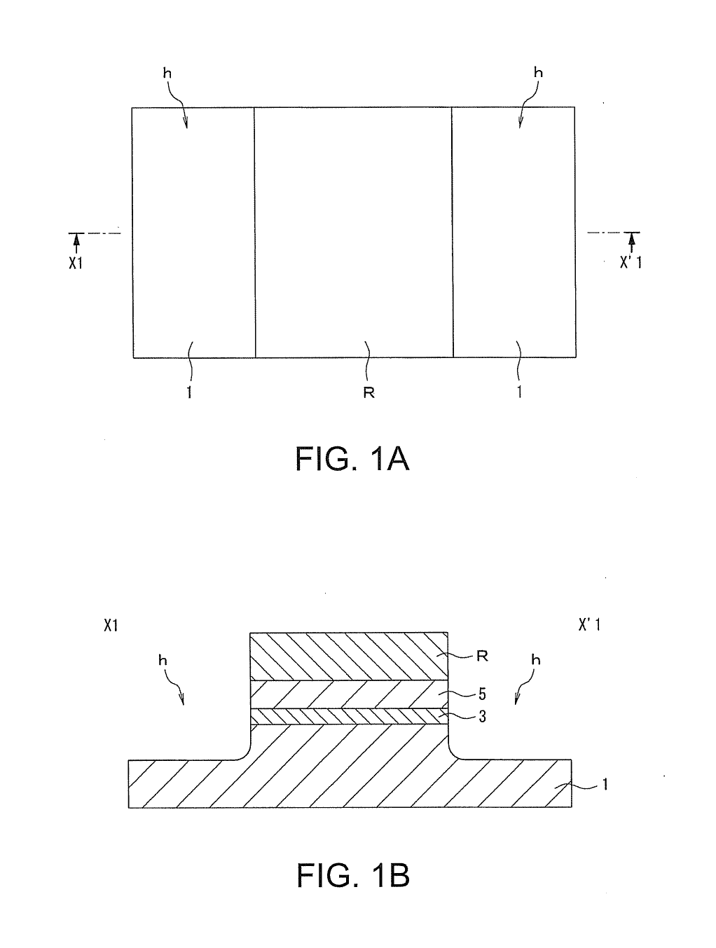

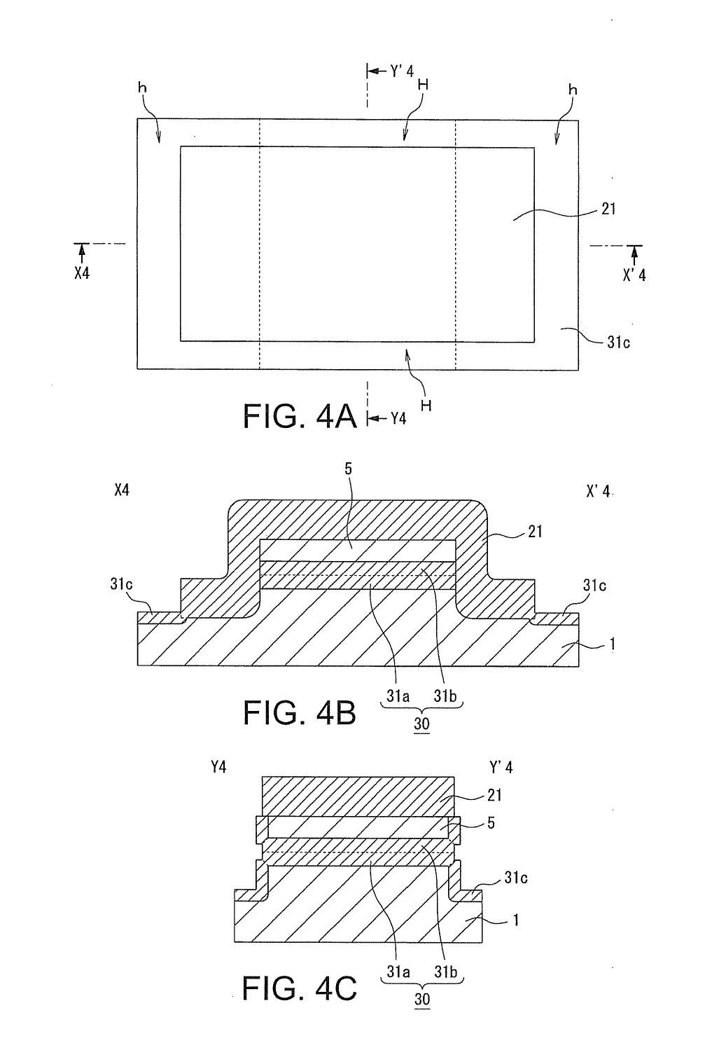

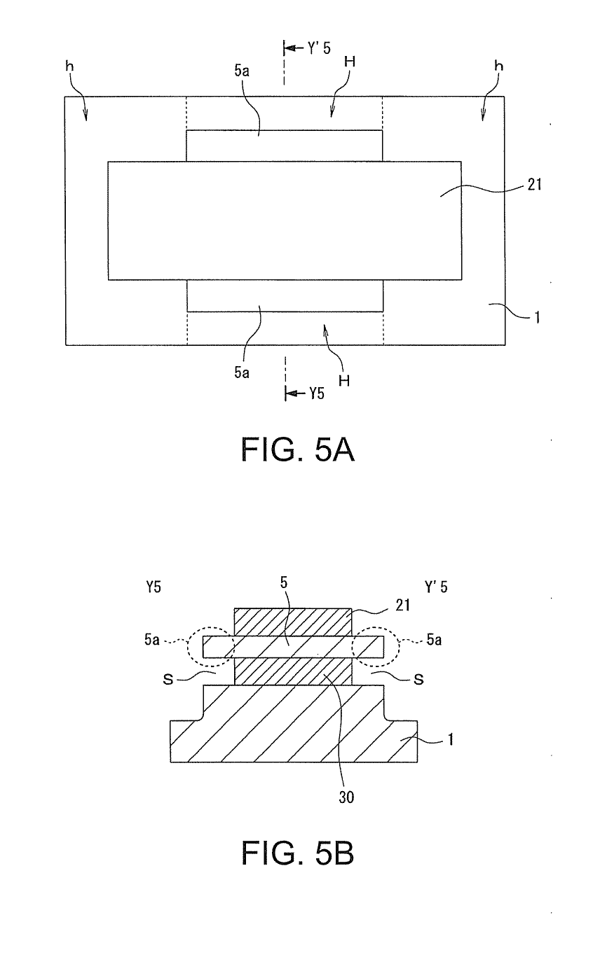

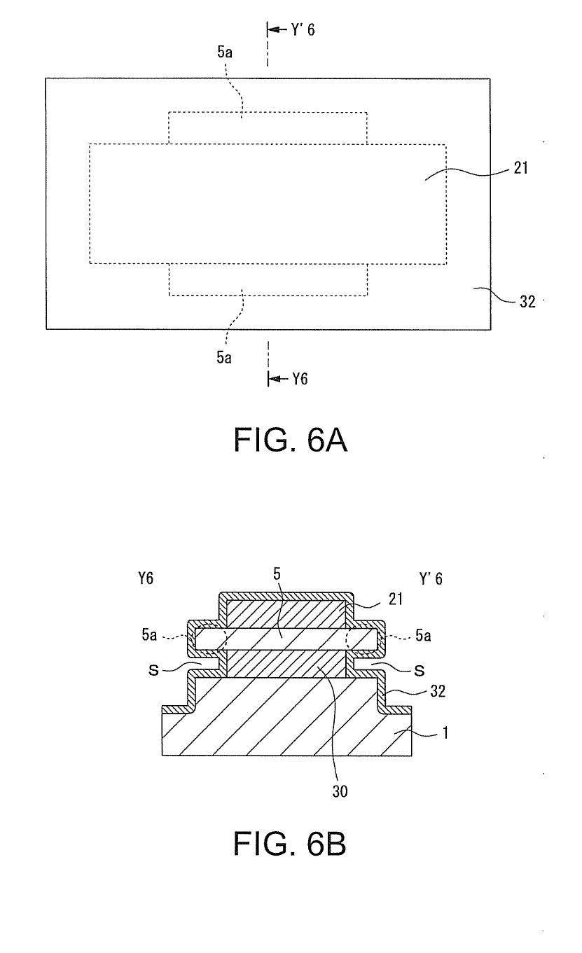

FIGS. 1A to 9B are schematic views showing a method for manufacturing a semiconductor device according to a first embodiment of the invention. In FIGS. 1A to 6B, figures suffixed with the letter “A” are plan views. In terms of FIGS. 1A to 4C, figures suffixed with the letter “B” are sectional views respectively taken along lines X1-X′1 to X4-X′4 of the figures suffixed with the letter “A”. In terms of FIGS. 5A to 6B, FIGS. 5B and 6B are sectional views respectively taken along lines Y5-Y′5 of FIG. 5A and Y6-Y′6 of FIG. 6A. FIG. 4C is a sectional view taken along a line Y4-Y′4 of FIG. 4A.

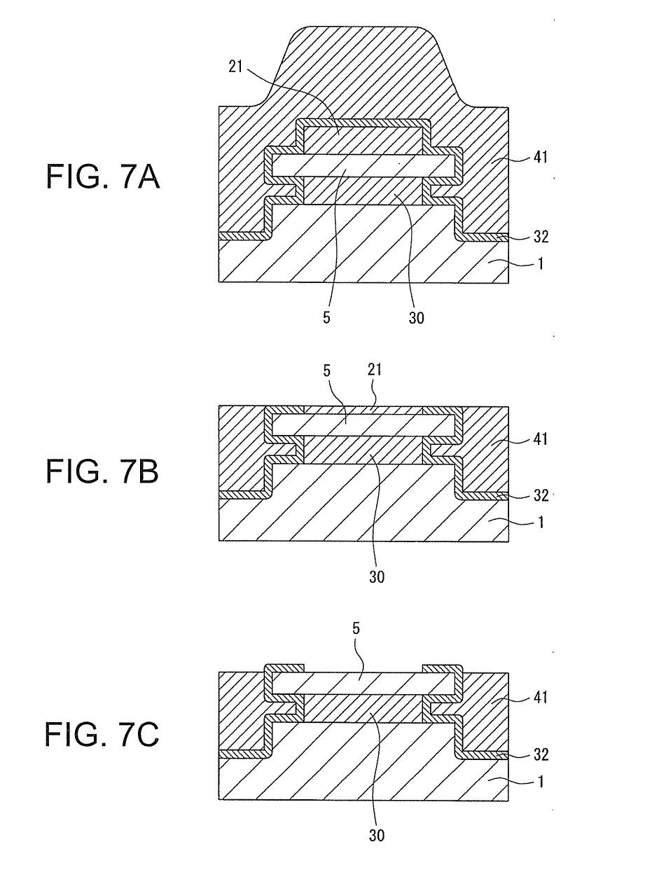

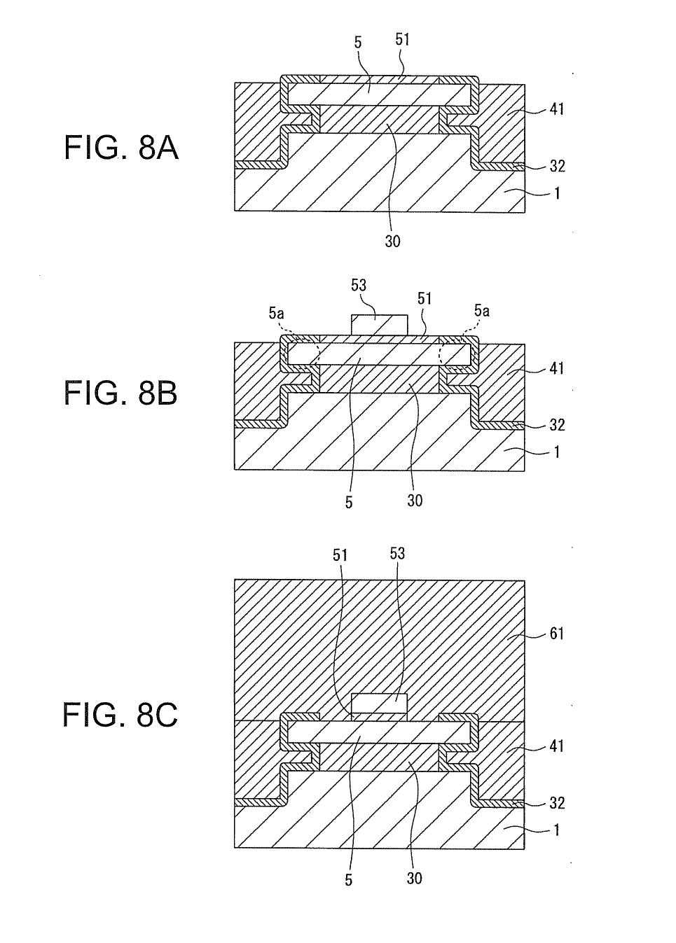

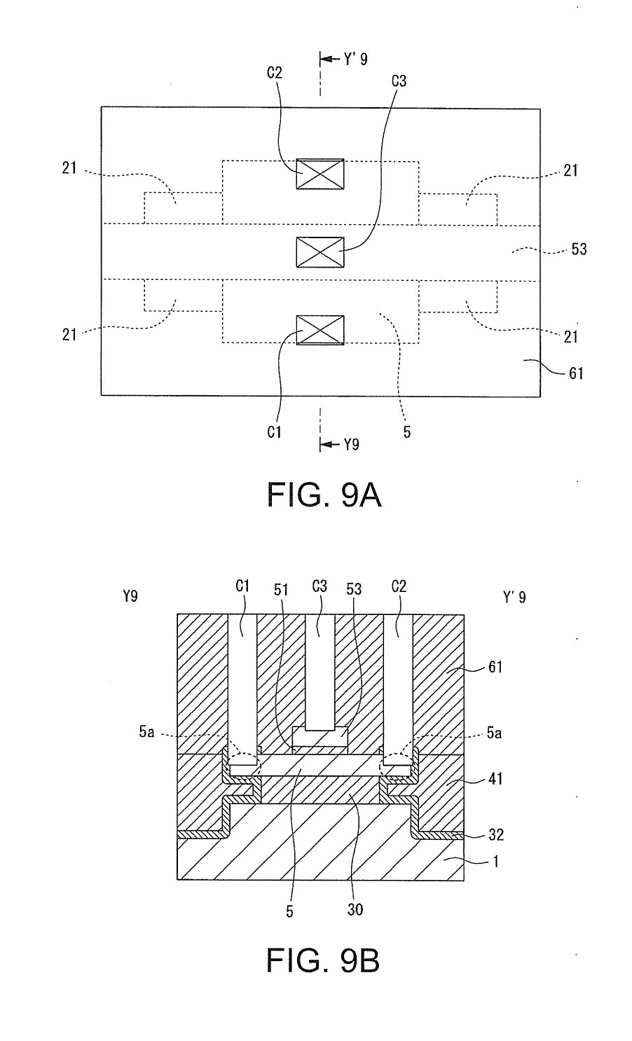

FIGS. 7A to 8C are sectional views taken at a Y6-Y′6 section of FIG. 6B and showing the manufacturing method after FIG. 6B. Further, FIG. 9A is a plan view, and FIG. 9B is a sectional view taken along a line Y9-Y′9 of FIG. 9A.

Referring to FIGS. 1A and 1B, a silicon germanium (SiGe) layer 3 and a Si layer 5 that have a single crystal structure are sequentially layered on a Si substrate 1, first. The SiGe layer 3 and the Si layer 5 are formed in succession by epitaxial growth, for example.

Here, before the SiGe layer 3 is formed, a silicon buffer (Si-buffer) layer that has a single crystal structure and is not shown may be thinly formed on the Si substrate 1. Then the SiGe layer 3 and the Si layer 5 may be sequentially formed thereon. In this case, it is preferable that the Si-buffer layer, the SiGe layer 3, and the Si layer 5 be sequentially formed by epitaxial growth, for example. Film quality of a semiconductor film that is formed by epitaxial growth is largely affected by a crystalline state of a surface where the film is formed (that is, a foundation). Therefore, instead of directly forming the SiGe layer 3 on the Si substrate 1, the Si-buffer layer that has smaller crystal defect than the surface of the Si substrate 1 is interposed between the Si substrate 1 and the SiGe layer 3, being able to achieve an improvement of film quality (reduction of crystal defects, for example) of the SiGe layer 3.

Next, a resist pattern R is formed on the Si layer 5. The resist pattern R has such shape that covers an element region (that is, a region for forming an SOI structure) and a region for forming a groove H that is used for removing SiGe, and exposes a region for forming a support recess h. Then anisotropic dry etching is conducted with respect to the Si layer 5 and the SiGe layer 3 while using the resist pattern R as a mask so as to form the support recess h. In the etching for forming the support recess h, the etching may be stopped at the surface of the Si substrate 1, or the Si substrate 1 may be over-etched so as to form an indentation as shown in FIG. 1B. Then, the resist pattern R is removed by ashing, for example. After that, a support film (not shown) is formed over the whole surface of the Si substrate 1 so as to fill the support recess h. The support film is, for example, a silicon oxide (SiO₂) film, and it is formed by CVD. The thickness of the support film is, for example, about 400 nm.

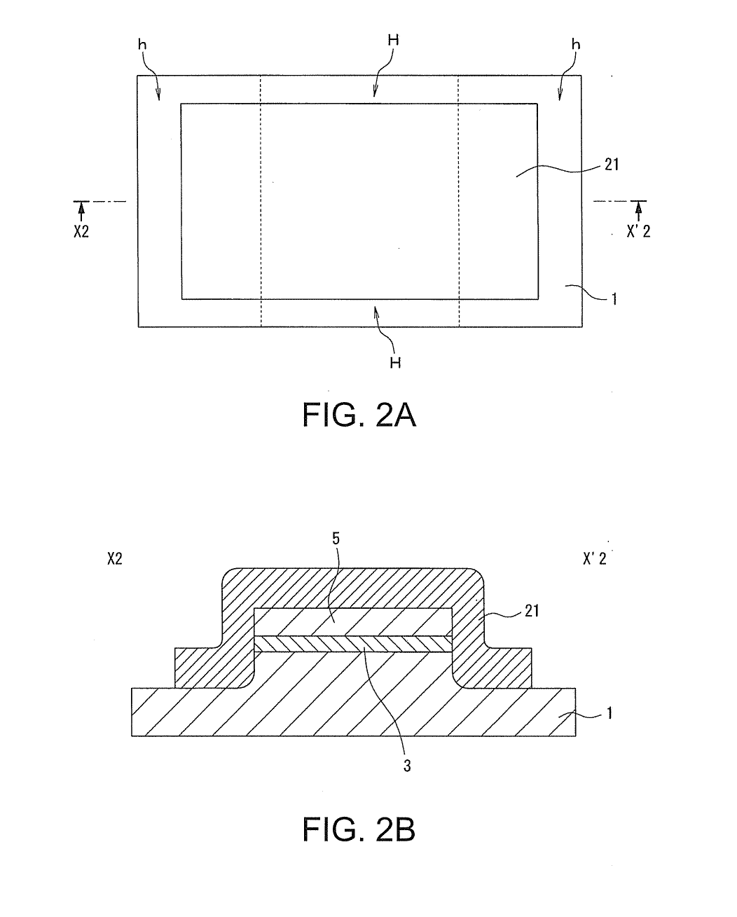

As shown in FIGS. 2A and 2B, a part of each of the support film, the Si layer 5, and the SiGe layer 3 is etched in sequence by photolithography and dry-etching, for example. The part is in an area overlapping with an element isolation region when viewed from above. Thus a support 21 is formed from the support film, and the groove H that exposes each lateral surface of the Si layer 5 and the SiGe layer 3 and exposes the Si substrate 1 as a bottom surface thereof is formed. Here, the groove H serves as an inlet of an etchant when the SiGe layer 3 is etched later. In the etching for forming the groove H, the etching of the SiGe layer 3 may be stopped before reaching the Si substrate 1 to leave a part of the SiGe layer 3 on the Si substrate 1 or the Si substrate 1 may be over-etched so as to form an indentation.

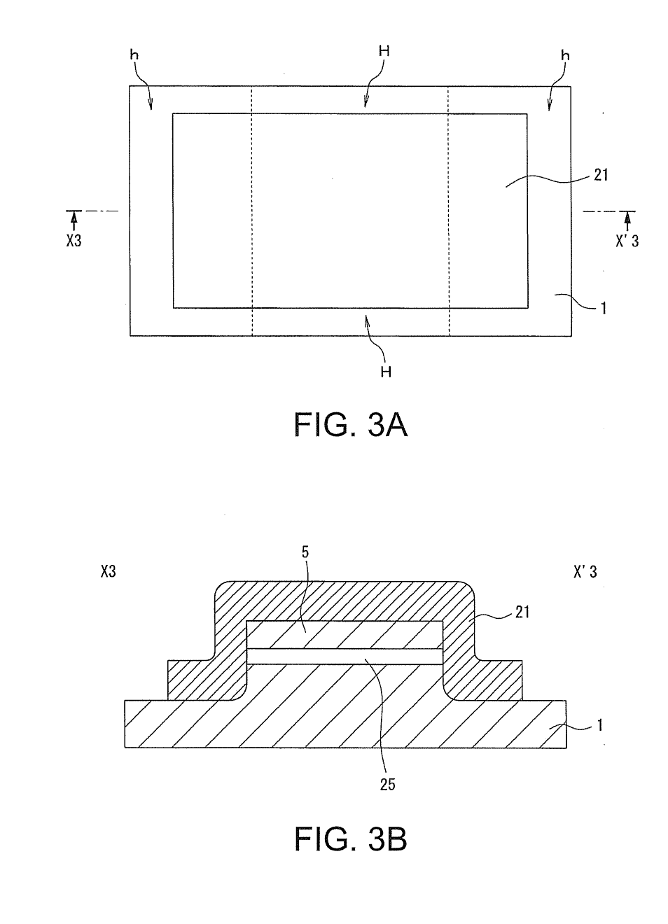

Then, a hydrofluoric-nitric acid solution, for example, is brought into contact with respective lateral surfaces of the Si layer 5 and the SiGe layer 3 through the groove H so as to selectively etch and remove the SiGe layer 3. Accordingly, a cavity 25 is formed between the Si layer 5 and the Si substrate 1 as shown in FIGS. 3A and 3B. In wet etching with a hydrofluoric-nitric acid solution, since an etching rate of SiGe is higher than that of Si (that is, etching selective ratio with respect to Si is high), only the SiGe layer 3 can be removed by etching while leaving the Si substrate 1 and the Si layer 5. In the middle of forming the cavity 25, the upper surface and the lateral surface of the Si layer 5 start to be supported by the support 21.

Next, the Si substrate 1 is placed in an oxidizing atmosphere of oxygen (O₂) or the like so as to thermally oxidize the Si substrate 1 and the Si layer 5, forming a SiO₂ film 30 (that is, a BOX layer) in the cavity as shown in FIGS. 4A to 4C. In the forming process of the BOX layer 30, a surface exposed from under the support 21 is thermally oxidized, forming a SiO₂ film 31c. Further, the upper surface of the Si substrate 1 and the lower surface of the Si layer 5 are thermally oxidized in the cavity 25. Thus a SiO₂ film 31a grows from the upper surface of the Si substrate 1 to the inside of the cavity 25 and a SiO₂ film 31b grows from the lower surface of the Si layer 5 to the inside of the cavity 25. Then the SiO₂ films 31a and 31b contact each other firmly near the center of the cavity 25 so as to form the BOX layer 30 composed of the SiO₂ films 31a and 31b. The thickness of the BOX layer 30 is about 50 to 100 nm, for example.

Treatment conditions (time and a temperature of the thermal oxidation, for example) for firmly contacting the SiO₂ films 31a and 31b in the cavity 25 vary depending on the inside height of the cavity 25 in a state before the thermal oxidation. Therefore, it is preferable that experimentation or a simulation be conducted before a semiconductor device is manufactured so as to derive the most appropriate treatment condition with respect to the inside height of the cavity.

Next, as shown in FIGS. 5A and 5B, the BOX layer 30 is wet-etched from its lateral surface with a dilute hydrofluoric acid (HF) solution, for example. Here, the “lateral surface” is a surface that faces the groove H. Thus a gap S is formed between a peripheral part 5a of the Si layer 5 and the Si substrate 1. Here, in a case where the support 21 is made of SiO₂, the support 21 is also wet-etched with the dilute HF solution. Therefore, as shown in FIGS. 5A and 5B, the peripheral part 5a of the Si layer 5 is exposed from under the support 21.

As shown in FIGS. 6A and 6B, a Si₃N₄ film 32 is formed over the whole top surface of the Si substrate 1 including the support 21 by CVD. In this process, a gas for forming a film enters the gap S described above so as to form the Si₃N₄ film 32 on the Si substrate 1, the BOX layer 30, and the peripheral part of the Si layer 5 that face the gap S, in succession. That is, the Si₃N₄ film 32 is formed on the upper surface, facing the gap S, of the Si substrate 1; the lateral surface, facing the groove H, of the BOX layer 30; and the lower surface of the peripheral part 5a of the Si layer 5. Further, the Si₃N₄ film 32 is formed on the lateral surface facing the groove H and the upper surface of the peripheral part 5a. The film thickness of the Si₃N₄ film 32 is about 20 to 50 nm, for example.

While FIG. 6B shows a structure that the Si₃N₄ film 32 is thinly formed without filling the gap S even after the Si₃N₄ film 32 is formed, the invention is not limited to the structure. The Si₃N₄ film 32 may be formed thickly so as to fill the gap S completely.

Next, as shown in FIG. 7A, a SiO₂ film 41, for example, is formed thickly over the whole top surface of the Si substrate 1 so as to fill the support recess h and the groove H (refer to FIG. 5A for both, for example). The SiO₂ film 41 is formed by CVD, for example. Then the SiO₂ film 41, the Si₃N₄ film 32, and the support 21 are planarized by, for example, CMP as shown in FIG. 7B. Further, the support 21 covering the Si layer 5 is wet-etched with a dilute HF solution, for example.

This wet-etching completely removes the support 21 from the Si layer (hereinafter, referred to as the “SOI layer”) 5, completing the SOI structure composed of the BOX layer 30 and the SOI layer 5 in the element region on the Si substrate 1, as shown in FIG. 7C. The SiO₂ film 41 and the support 21 fill a region other than the element region on the Si substrate 1, and this region functions as an element isolation layer.

Next, a MOS transistor is formed on the SOI layer 5 that is electrically isolated from the Si substrate 1 by the SiO₂ film 41, the support 21, and the BOX layer 30. Namely, the surface of the SOI layer 5 is thermally oxidized so as to form a gate oxide layer 51, as shown in FIG. 8A. Then polysilicon and the like are provided by CVD, for example, on the SOI layer 5 provided with the gate oxide film 51. Further, the polysilicon and the like are patterned by photolithography and dry-etching so as to form a gate electrode 53, as shown in FIG. 8B.

Next, an impurity such as As, P, and B, is ion implanted into the SOI layer 5 while using the gate electrode 53 as a mask to form a lightly doped drain (LDD). An insulating layer is layered on the SOI layer 5 provided with the LDD, and the insulating layer is etched back so as to form a side wall (not shown) on a lateral wall of the gate electrode 53. Then an impurity such as As, P, and B is ion implanted into the SOI layer 5 while using the gate electrode 53 and the side wall as a mask. After that, a heat treatment is conducted so as to activate the impurity. Thus a source and a drain (not shown) having the LDD are formed at both sides of the gate electrode 53 (including the peripheral part 5a) on the SOI layer 5.

After the source and the drain are formed, a silicide film (not shown) may be formed on the source, the drain, and the gate electrode 53 respectively by salicide (self-align salicide) process.

An interlayer insulation film 61 is next layered over the whole upper surface of the Si substrate 1 by CVD, for example, so as to cover the gate electrode 53 and the like, as shown in FIG. 8C. The interlayer insulation film 61 is a SiO₂ film, for example. Then the interlayer insulation film 61 is partially etched to be removed by photolithography and dry-etching. Thus contact holes C1 to C3 are respectively formed on the source and the drain that are formed on the SOI layer 5, and the gate electrode 53, as shown in FIGS. 9A and 9B.

Here, the present embodiment forms the source and the drain on the peripheral part 5a of the Si layer 5, and forms the contact hole C1 communicating with the source and the contact hole C2 communicating with the drain directly above the peripheral part 5a respectively. That is, the contact holes C1 and C2 are formed directly above the Si₃N₄ film 32. The Si₃N₄ film 32 is harder to be etched than the SiO₂ film 41. Therefore, even if dry-etching for forming the contact holes C1 and C2 is conducted excessively such that the peripheral part 5a of the SOI layer 5 is penetrated, the progress of the etching can be stopped at the Si₃N₄ film 32.

After the contact holes C1 to C3 are formed as above, a metal film (not shown) made of tungsten (W), for example, is formed by CVD or sputtering. Then the metal film is planarized or patterned by photolithography and dry-etching so as to form a contact electrode (not shown) in each of the contact holes C1 to C3.

According to the first embodiment of the invention, even if the partial etching of the interlayer insulation film 61 for forming the contact holes C1 to C3 is conducted excessively such that the SOI layer 5 is penetrated, the progress of the etching can be stopped at the Si₃N₄ film 32. Therefore the contact holes C1 and C2 can be prevented from reaching the surface of the Si substrate 1, being able to prevent such defect that the source and the drain of the MOS transistor (that is, the SOI transistor) formed on the SOI layer 5 are short-circuited through the Si substrate 1. Consequently, a semiconductor device having high reliability can be provided.

A related art SOI device and a related art method for forming a BOX layer with SBSI have had a very small process margin in forming a contact hole. However, the method of the embodiment can sufficiently treat the over-etching in contact hole processing, being able to increase the process margin. Therefore, a preferable contact property with respect to the SOI layer can be obtained.

### Second Embodiment

The first embodiment describes a case where the MOS transistor is formed on the Si layer (also, referred to as the SOI layer) 5 in a state that the Si₃N₄ film 32 is left at the peripheral part 5a of the SOI layer 5, as shown in FIG. 8A. However, the Si₃N₄ film 32 may be completely removed from the peripheral part 5a before the MOS transistor is formed on the SOI layer 5. A second embodiment will describe such structure.

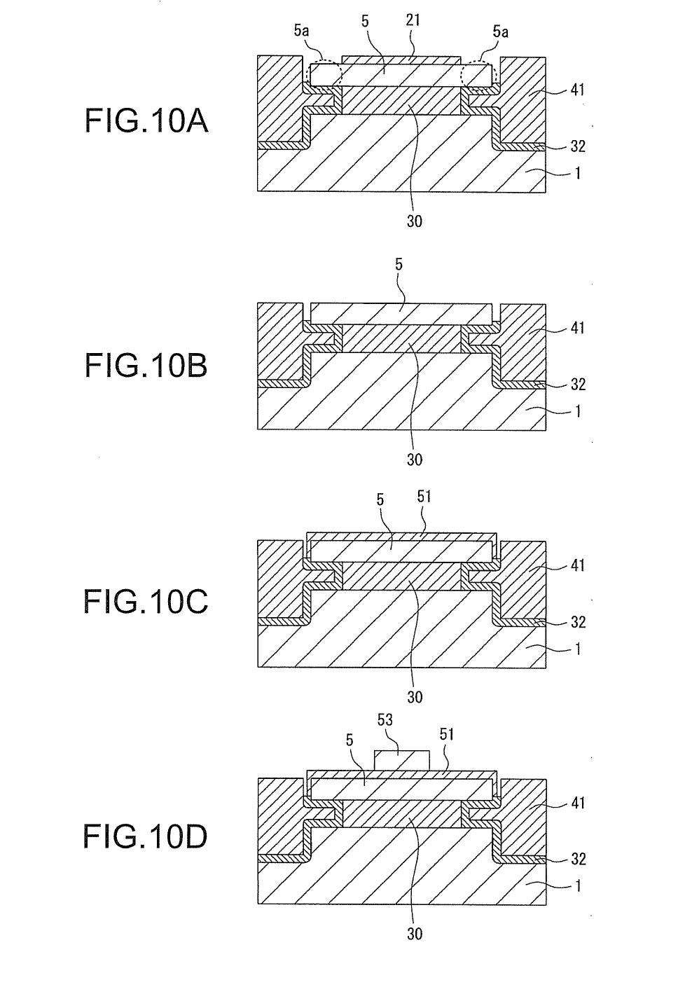

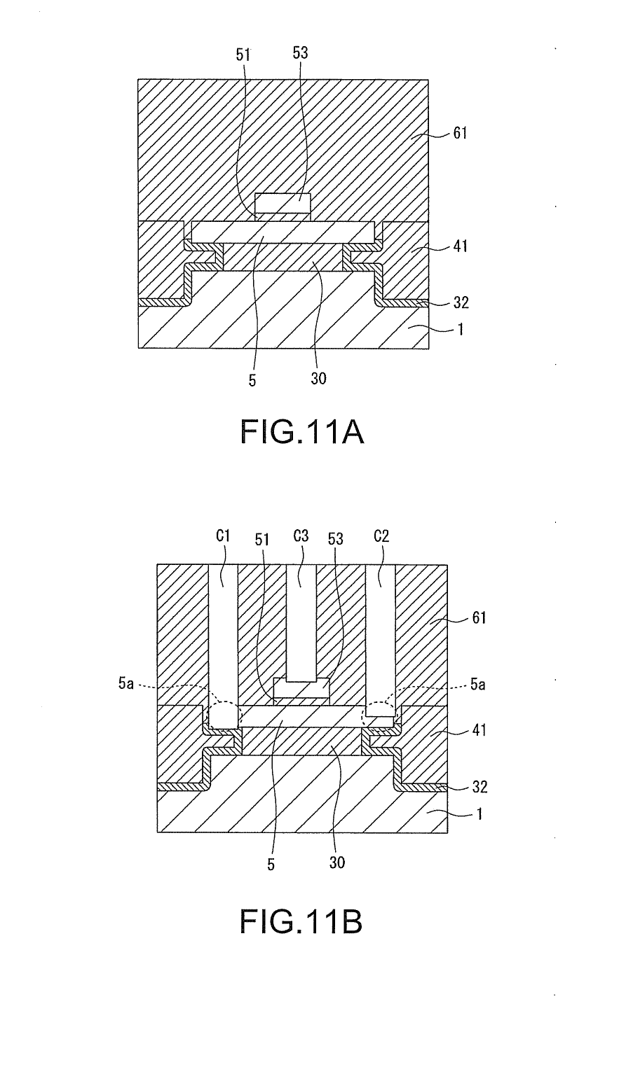

FIGS. 10A to 11B are sectional views showing a method for manufacturing a semiconductor device according to the second embodiment. In FIGS. 10A to 11B, portions having the same structure and function as those in FIGS. 1A to 9B described in the first embodiment are denoted by the same reference numerals, and descriptions thereof will be omitted.

The second embodiment has the same process as the first embodiment up to the process for planarizing the SiO₂ film 41, the Si₃N₄ film 32, and the support 21 by CMP. After the completion of the planarization by CMP shown in FIG. 7B, the Si₃N₄ film 32 is removed from the upper surface of the peripheral part 5a of the SOI layer 5 as shown in FIG. 10A. The removing of the Si₃N₄ film 32 is conducted by dry-etching or wet-etching with a heated phosphoric acid solution, for example. After the removing process of the Si₃N₄ film 32, the support 21 formed on the SOI layer 5 is wet-etched and removed with a dilute HF solution, for example.

The remove of the support 21 and the Si₃N₄ film 32 exposes the whole upper surface of the SOI layer 5 as shown in FIG. 10B. Next, the surface of the SOI layer 5 is thermally oxidized so as to form a gate oxide film 51, as shown in FIG. 10C. Then the gate electrode 53 made of polysilicon, for example, is formed on the gate oxide film 51, as shown in FIG. 10D. Next, an impurity such as As, P, and B, is ion implanted into the SOI layer 5 while using the gate electrode 53 as a mask, a side wall is formed as necessary, and heat treatment for activating the impurity is conducted. Thus a source and a drain (not shown) are formed at the both sides of the gate electrode 53 on the SOI layer 5 (including the peripheral part 5a). A silicide film (not shown) may be formed on the gate electrode 53, the source, and the drain depending on the case.

The interlayer insulation film 61 is next layered over the whole upper surface of the Si substrate 1 by CVD, for example, so as to cover the gate electrode 53 and the like, as shown in FIG. 11A. Then the interlayer insulation film 61 is partially dry-etched and removed so as to form the contact holes C1 to C3 as shown in FIG. 11B. Then a metal film (not shown) made of tungsten (W), for example, is formed by CVD or sputtering, and the film is patterned so as to form a contact electrode (not shown) in each of the contact holes C1 to C3.

Thus the second embodiment provides the Si₃N₄ film 32 between the peripheral part 5a of the SOI layer 5 and the Si substrate 1. Therefore, even if the dry-etching for forming the contact holes C1 and C2 is conducted excessively such that the contact holes C1 and C2 penetrate through the SOI layer 5, the progress of the dry-etching can be stopped at the Si₃N₄ film 32, in the same manner as the first embodiment. Consequently, a semiconductor device having high reliability can be provided.

In terms of the first and second embodiments, the Si substrate 1 exemplarily corresponds to a “semiconductor substrate” of the invention, the SiGe layer 3 exemplarily corresponds to a “first semiconductor layer” of the same, and the Si layer (the SOI layer) 5 exemplarily corresponds to a “second semiconductor layer” and to a “semiconductor layer” of the same. Further, the support recess h and the grove H exemplarily correspond to a “second groove” and a “first groove” of the invention, respectively. Furthermore, the SiO₂ film (the BOX layer) 30 exemplarily corresponds to an “embedded oxide film” and an “insulating layer” of the invention, and the Si₃N₄ film 32 exemplarily corresponds to an “etching stopper layer” of the same.

### Third Embodiment

The present invention is applicable to a multilayered structure having a back gate. A third embodiment will describe such structure.

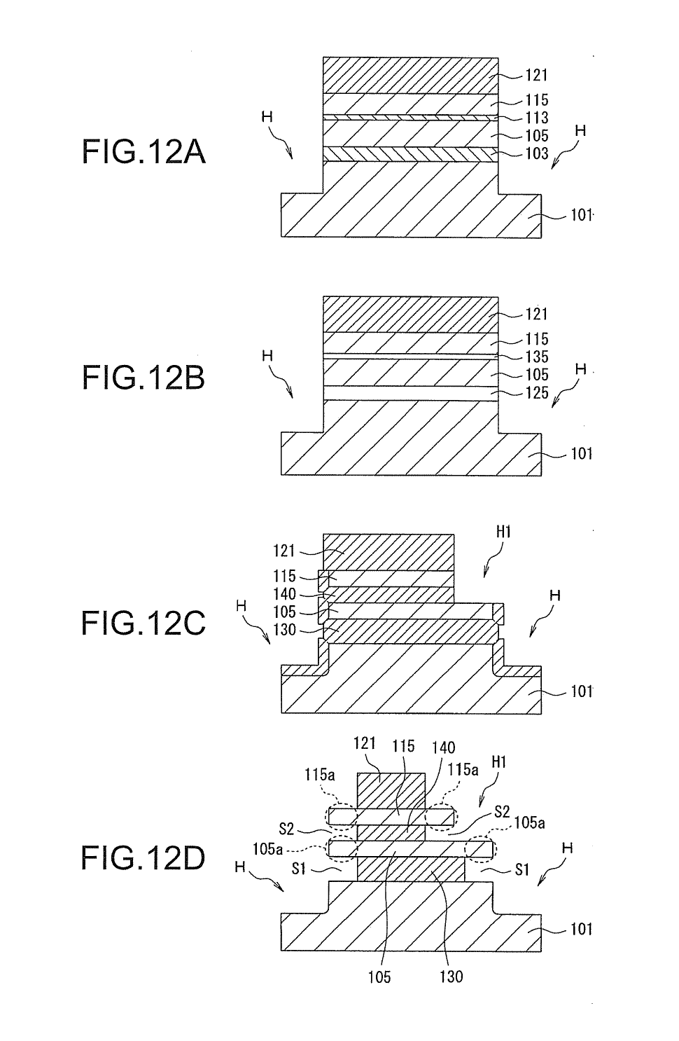

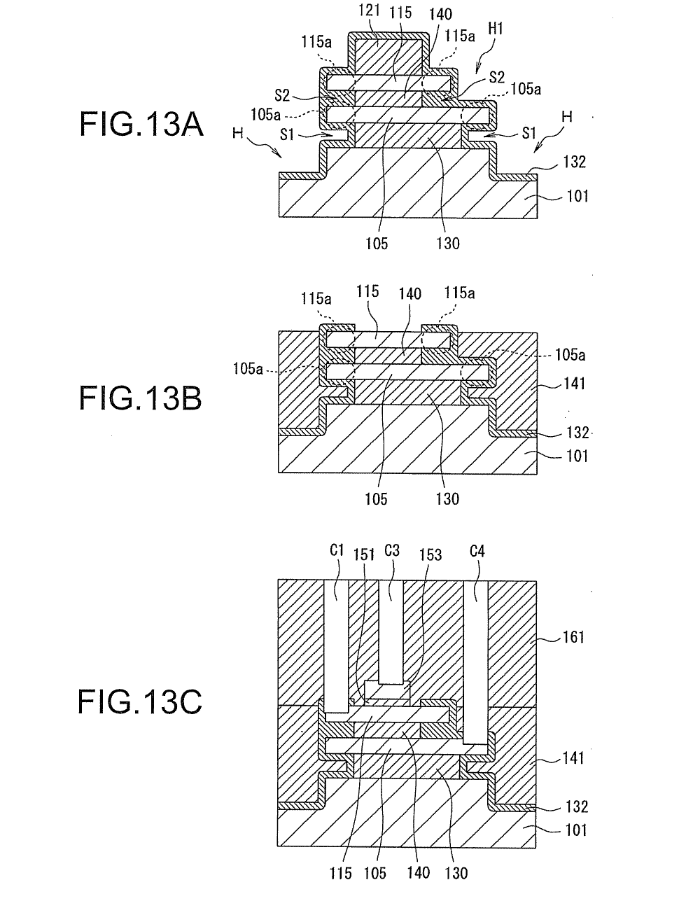

FIGS. 12A to 13C are sectional views showing a method for manufacturing a semiconductor device according to a third embodiment.

As shown in FIG. 12A, the third embodiment sequentially layers a SiGe layer 103, a Si layer 105, a SiGe layer 113, and a Si layer 115 on a Si substrate 101. These layers have a single crystalline structure. Here, the Si layer 105 is used as a back gate electrode for adjusting a threshold value of a SOI transistor. Further, to the Si layer 115, a MOS transistor and the like are to be provided in a later process. The SiGe layer 103, the Si layer 105, the SiGe layer 113, and the Si layer 115 are sequentially formed by epitaxial growth, for example.

Then the SiGe layer 103, the Si layer 105, the SiGe layer 113, and the Si layer 115 are partially etched in sequence by photolithography and dry-etching so as to form the support recess h (refer to FIGS. 1A and 1B, for example). After that, a support film is formed over the whole upper surface of the Si substrate 101 in a manner filling the support recess h. The support film is a SiO₂ film, for example. Then a part of each of the support film, the Si layer 115, the SiGe layer 113, the Si layer 105, and the SiGe layer 103 is sequentially etched by photolithography and dry-etching, for example. The part is overlapped with the element isolation region when viewed from above. Thus a support 121 is formed from the support film, and the groove H that exposes each lateral surface of the Si layer 115, the SiGe layer 113, the Si layer 105, and the SiGe layer 103 and exposes the Si substrate 101 as a bottom surface thereof is formed.

Next, a hydrofluoric-nitric acid solution, for example, is brought into contact with respective lateral surfaces of the Si layer 115, the SiGe layer 113, the Si layer 105, and the SiGe layer 103 through the groove H so as to selectively etch and remove the SiGe layer 113 and the SiGe layer 103. This etching forms a first cavity 125 between the Si substrate 101 and the Si layer 105 and a second cavity 135 between the Si layer 105 and the Si layer 115, as shown in FIG. 12B. In the middle of forming the cavities 125 and 135, an upper surface and a lateral surface of the Si layer 115; and a lateral surface of the Si layer 105 start to be supported by the support 121.

Next, the Si substrate 101 is placed in an oxidizing atmosphere of oxygen (O₂), for example, so as to thermally oxidize the upper surface of the Si substrate 101 and the lower surface of the Si layer 105 that face the inside of the cavity 125, and the upper surface of the Si layer 105 and the lower surface of the Si layer 115 that face the inside of the cavity 135. The thermal oxidation forms a BOX layer 130 made of SiO₂ in the first cavity 125, and a BOX layer 140 made of SiO₂ in the second cavity 135 as shown in FIG. 12C. After the BOX layers 130 and 140 are formed, the Si layer (the SOI layer) 115 and the BOX layer 140 are partially etched so as to form a groove H1 of which a bottom surface is a peripheral part 105a of the Si layer 105.

Next, the BOX layer 130 and the BOX layer 140 are wet-etched from their lateral surfaces with a dilute HF solution, as shown in FIG. 12D. Here, the “lateral surface” means a surface facing the groove H or the groove H1. Thus a gap S1 is formed between the peripheral part 105a of the Si layer 105 and the Si substrate 101, and a gap S2 is formed between a peripheral part 115a of the Si layer 115 and the Si layer 105. Here, in a case where the support 121 is made of SiO₂, the support 121 is also wet-etched with the dilute HF solution, so that the peripheral part 115a of the Si layer 115 protrudes from the support 121 as shown in FIG. 12D.

As shown in FIG. 13A, a Si₃N₄ film 132 is formed over the whole top surface of the Si substrate 101 including the support 121 by CVD. In this process, a gas for forming a film enters the gap S1 described above so as to form the Si₃N₄ film 132 on the upper surface of the Si substrate 1, the lateral surface of the BOX layer 130, and the lower surface of the peripheral part 105a of the Si layer 105 that face the gap S1 in succession. The gas for forming a film enters the gap S2 described above as well so as to form the Si₃N₄ film 132 on the upper surface of the peripheral part 105a, the lateral surface of the BOX layer 140, and the lower surface of the Si layer 115 that face the gap S2, in succession.

While FIG. 13B shows a structure that the Si₃N₄ film 132 is thinly formed without filling the gap S1 completely even after the Si₃N₄ film 132 is formed, the invention is not limited to the structure. The Si₃N₄ film 132 may be formed thickly so as to fill the gap S1 completely.

Then a SiO₂ film, for example, is thickly formed over the whole of the upper surface of the Si substrate 101 so as to fill the support recess h and the grooves H and H1 (refer to FIG. 5A, for example). After that, the SiO₂ film that is thickly formed and the support 121 that is formed under the SiO₂ film are planarized by CMP, for example, and wet-etched with a dilute HF solution. Thus, as shown in FIG. 13B, the support 121 is completely removed from the Si layer (also, referred to as the SOI layer) 115, completing the multilayered structure composed of the BOX layer 130, the Si layer 105, the BOX layer 140, and the Si layer 115 on the Si substrate 101. The SiO₂ film 141 and the support 121 fill a region other than the element region on the Si substrate 101, and this region functions as an element isolation layer.

Next, the surface of the SOI layer 115 is thermally oxidized so as to form a gate oxide film 151, as shown in FIG. 13C. Then a gate electrode 153 made of polysilicon, for example, is formed on the gate oxide film 151. After that, an impurity for forming a source and a drain is implanted into the SOI layer 115 and then a heat treatment is conducted so as to activate the impurity. Thus a source and a drain are respectively formed on both sides of the gate electrode 153 on the SOI layer 115 (including the peripheral part 115a). A silicide film (not shown) may be formed on the gate electrode 153, the source, and the drain depending on the case.

Then an interlayer insulation film 161 is next layered over the whole upper surface of the Si substrate 101 by CVD, for example, so as to cover the gate electrode 153 and the like, as shown in FIG. 13C. Then the interlayer insulation film 161 is partially dry-etched and removed so as to form a contact hole C1, a contact hole C3, and a contact hole C4 respectively on the source, the gate electrode 153, and the Si layer (that is, the back gate electrode) 105. A contact hole for coupling the drain is formed at the front (or back) side of the figure, thought it is not shown. After that, a metal film (not shown) made of tungsten (W), for example, is formed by CVD or sputtering, and the film is patterned so as to form a contact electrode (not shown) in each of the contact holes C1, C3, and C4.

Thus the third embodiment provides the Si₃N₄ film 132 between the peripheral part 115a of the SOI layer 115 and the Si layer (the back gate electrode) 105. Therefore, even if the dry-etching for forming the contact hole C1 is conducted such that the contact hole C1 penetrates through the SOI layer 115, the progress of the dry-etching can be stopped at the Si₃N₄ film 132, in the same manner as the first and second embodiments. Therefore, a defect that the source and the drain of the SOI transistor are short circuited through the Si layer (back gate electrode) 105 can be prevented. Consequently, a semiconductor device having high reliability can be provided.

Further, the third embodiment forms the Si₃N₄ film between the peripheral part 105a of the Si layer (back gate electrode) 105 and the Si substrate 101 as well. Therefore, even if the dry-etching for forming the contact hole C4 is conducted such that the contact hole C4 penetrates through the Si layer (the back gate electrode) 105, the progress of the dry-etching can be stopped at the Si₃N₄ film 132. Accordingly, a defect that a back gate bias is applied to the Si substrate 101 involuntarily can be prevented.

In terms of the third embodiment, the Si substrate 101 exemplarily corresponds to a “semiconductor substrate” of the invention, the SiGe layer 103 exemplarily corresponds to a “first semiconductor layer” of the same, and the Si layer (back gate electrode) 105 exemplarily corresponds to a “second semiconductor layer” of the same. In addition, the SiGe layer 113 exemplarily corresponds to a “third semiconductor layer” of the invention, and the Si layer (SOI layer) 115 exemplarily corresponds to a “fourth semiconductor layer” of the same. Further, the cavity 125 exemplarily corresponds to a “first cavity” of the invention, the cavity 135 exemplarily corresponds to a “second cavity” of the same, and the groove H exemplarily corresponds to a “groove” of the same. The SiO₂ film (BOX layer) 130 exemplarily corresponds to a “first embedded oxide film” of the invention, and the SiO₂ film (BOX layer) 140 exemplarily corresponds to a “second embedded oxide film” of the same. The Si₃N₄ film 132 exemplarily corresponds to an “etching stopper layer” of the invention.

What is claimed is:

1. A method for manufacturing a semiconductor device, comprising:
a) forming a first semiconductor layer on a semiconductor substrate;
b) forming a second semiconductor layer on the first semiconductor layer;
c) sequentially etching a part of the second semiconductor layer and a part of the first semiconductor layer so as to form a first groove exposing the first semiconductor layer;
d) forming a cavity between the semiconductor substrate and the second semiconductor layer by etching the first semiconductor layer through the first groove under an etching condition in which the first semiconductor layer is more easily etched than the second semiconductor layer;
e) forming an embedded oxide film in the cavity;
f) etching the embedded oxide film from a lateral surface side thereof so as to form a gap between a peripheral part of the second semiconductor layer and the semiconductor substrate; and
g) forming an insulating etching stopper layer in the gap.

2. The method for manufacturing a semiconductor device according to claim 1, further comprising: between the step b) and the step d),
h) partially etching the second semiconductor layer and the first semiconductor layer so as to form a second groove penetrating the second semiconductor layer and the first semiconductor layer; and
i) forming a support supporting the second semiconductor layer at least in the second groove.

3. The method for manufacturing a semiconductor device according to claim 1, further comprising:
j) forming a transistor on the second semiconductor layer;
k) forming an interlayer insulation film over the semiconductor substrate in a manner covering the transistor; and
l) partially etching the interlayer insulation film so as to form a contact hole on one of a source and a drain of the transistor, wherein in the step j), one of the source and the drain is formed at the peripheral part that positions directly above the etching stopper layer.

4. A method for manufacturing a semiconductor device, comprising:
a) forming a first semiconductor layer on a semiconductor substrate;
b) forming a second semiconductor layer on the first semiconductor layer;
c) forming a third semiconductor layer made of a same material as that of the first semiconductor layer on the second semiconductor layer;
d) forming a fourth semiconductor layer made of a same material as that of the second semiconductor layer on the third semiconductor layer;
e) partially etching the fourth semiconductor layer, the third semiconductor layer, the second semiconductor layer, and the first semiconductor layer in sequence so as to form a groove exposing the third semiconductor layer and the first semiconductor layer;
f) forming a first cavity between the semiconductor substrate and the second semiconductor layer; and a second cavity between the second semiconductor layer and the fourth semiconductor layer by etching the first semiconductor layer and the third semiconductor layer through the groove under a condition in which the first semiconductor layer is more easily etched than the second semiconductor layer;
g) forming a first embedded oxide film in the first cavity;
h) forming a second embedded oxide film in the second cavity;
i) partially etching the second embedded oxide film from a lateral surface side thereof so as to form a gap between a peripheral part of the fourth semiconductor layer and the second semiconductor layer; and
j) forming an insulating etching stopper layer in the gap.

5. The method for manufacturing a semiconductor device according to claim 4, further comprising: if the gap is defined as a first gap,
k) partially etching the first embedded oxide film from a lateral surface side thereof so as to form a second gap between a peripheral part of the second semiconductor layer and the semiconductor substrate; and
l) forming an etching stopper layer in the second gap as well.

6. A semiconductor device, comprising:
an insulating layer formed on a part of a semiconductor substrate;
a semiconductor layer formed on the insulating layer; and
an etching stopper layer that is formed between a peripheral part of the semiconductor layer and the semiconductor substrate without being formed between a center part of the semiconductor layer and the semiconductor substrate, wherein
one of a source and a drain of a transistor and a contact hole communicating with the one of the source and the drain are formed directly above the etching stopper layer.
